(19) United States
(12) Patent Application Publication
(10) Pub. No.: US 2010/0230738 A1
(43) Pub. Date: Sep. 16, 2010

(54) NOR FLASH MEMORY STRUCTURE WITH HIGHLY-DOPED DRAIN REGION AND METHOD OF MANUFACTURING THE SAME

(75) Inventors: Yider Wu, Chu-Pei City (TW); Yung-Chung Lee, Chu-Pei City (TW); Yi-Hsiu Chen, Chu-Pei City (TW)

Correspondence Address: SCHMEISER, OLSEN & WATTS, 22 CENTURY HILL DRIVE, SUITE 302, LATHAM, NY, 12110, US

(73) Assignee: EON SILICON SOLUTIONS INC., Chu-Pei City (TW)

(21) Appl. No.: 12/400,828

(22) Filed: Mar. 10, 2009

(51) Int. Cl. H01L 29/788; H01L 21/336; H01L 29/00

(52) U.S. Cl. 257/314; 438/257; 257/E29.3; 257/408; 257/E21.409; 438/283; 438/305

(57) ABSTRACT

In a method of manufacturing a NOR flash memory structure, a highly-doped ion implantation process is performed to form a highly-doped drain region to overlap with a lightly-doped drain region. Therefore, the flash memory structure can have a reduced drain junction depth to improve the short channel effect while protecting the lightly-doped drain region from being punched through during an etching process for forming a contact hole.

### FIELD OF THE INVENTION

The present invention relates to a NOR flash memory structure, and more particularly to a NOR flash memory structure with highly-doped drain region and to a method for manufacturing the NOR flash memory structure.

### BACKGROUND OF THE INVENTION

A flash memory is a non-volatile memory, which can maintain the information stored thereon even when no power is supplied thereto. This means an electronic device using the flash memory does not need to waste electric power for memorizing data. The flash memory is also rewritable, small in volume with high memory capacity, and easy to carry. Therefore, flash memories are particularly suitable for use with portable devices. Currently, NOR flash memories have been used not only on motherboards of computers for storing BIOS (basic input/output system) data, but also on mobile phones and hand-held devices for storing system data. In addition, the flash memory offers fast read access speed to satisfy the demands for quick boot speed of hand-held devices.

With the progress in different technical fields, the process technique for flash memory also moves into the era of nanometer technology. For the purpose of increasing the device operating speed, increasing the device integration, and reducing the device operating voltage, it has become a necessary trend to reduce the gate channel length and the oxide layer thickness of the device. The reduction of device dimensions increases not only the density of integrated circuit (IC) per unit area, but also the current driving ability of the device. However, there are also problems caused by such reduction of device dimensions. For example, the gate linewidth of the device has been reduced from the past micron scale (10⁻⁶ meter) to the current nano scale (10⁻⁹ meter), and the short channel effect (SCE) becomes more serious with the reduction of device dimensions and gate linewidth. One of the solutions to avoid influences of short channel effect on the device is to reduce the source/drain junction depth.

For instance, the lightly-doped drain (LDD) enables the device to have an increased breakdown voltage, improved critical voltage property, and reduced hot carrier effect. While the LDD reduces the high electric field at the drain junction and effectively upgrades the reliability of the device, the LDD with shallow junction depth tends to be punched through in the etching process for forming contact hole to thereby damage the memory structure.

Therefore, it is very important to improve the drain region to overcome the problem of punch-through during the etching process for forming contact hole.

### SUMMARY OF THE INVENTION

A primary object of the present invention is to provide a NOR flash memory with highly-doped drain region (HDD), so that the memory structure can have a drain region having a reduced junction depth to improve the SCE but not being subject to punch-through during the etching process for forming contact hole.

To achieve the above and other objects, the NOR flash memory structure with highly-doped drain region according to the present invention includes a semiconductor substrate having two gate structures formed thereon; a first drain region being a light-doped region and located in the semiconductor substrate between the two gate structures; two first source regions located in the semiconductor substrate at two outer sides of the two gate structures, and the first source regions each having a junction depth in the semiconductor substrate deeper than that of the first drain region; a highly-doped drain (HDD) region located in the semiconductor substrate between the two gate structures to overlap with the first drain region, and the HDD region having a junction depth in the semiconductor substrate deeper than that of the first drain region; two salicide layers separately located atop the two gate structures; and a barrier plug for isolating the two gate structures from each other.

Another object of the present invention is to provide a method of manufacturing a NOR flash memory structure with highly-doped drain region, so that the memory structure can have a drain region having a reduced junction depth to improve the SCE but not being subject to punch-through during the etching process for forming contact hole.

To achieve the above and other objects, the method of manufacturing a NOR flash memory structure with highly-doped drain region according to the present invention includes the following steps: providing a semiconductor substrate; forming two gate structures on the semiconductor substrate; performing a lightly-doped ion implantation process, so that a lightly-doped first drain region is formed in the semiconductor substrate between the two gate structures, and two lightly-doped source regions are formed in the semiconductor substrate at two outer sides of the two gate structures, and then further performing a source region ion implantation process, so that two first source regions are formed in the semiconductor substrate at two outer sides of the two gate structures, wherein the first source regions each have a junction depth in the semiconductor substrate deeper than that of the first drain region; forming two facing spacer walls between the two gate structures and above the first drain region; performing a highly-doped ion implantation process, so that a highly-doped drain (HDD) region is formed between the two gate structures to overlap with the first drain region, and the HDD region having a junction depth in the semiconductor substrate deeper than that of the first drain region; and forming a barrier plug between the two gate structures.

With the above arrangements and the above manufacturing method, the NOR flash memory structure according to the present invention can have a lightly-doped drain region that is not subject to punch-through during forming the contact hole by etching.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIGS. 1 to 8 are schematic sectional views of a NOR flash memory structure of the present invention at different stages when being manufactured using a method of the present invention.

### DETAILED DESCRIPTION OF THE PREFERRED EMBODIMENTS

The present invention will now be described with a preferred embodiment thereof. For the purpose of easy to understand, elements that are the same in the illustrated preferred embodiment and the accompanying drawings are denoted by the same reference numerals.

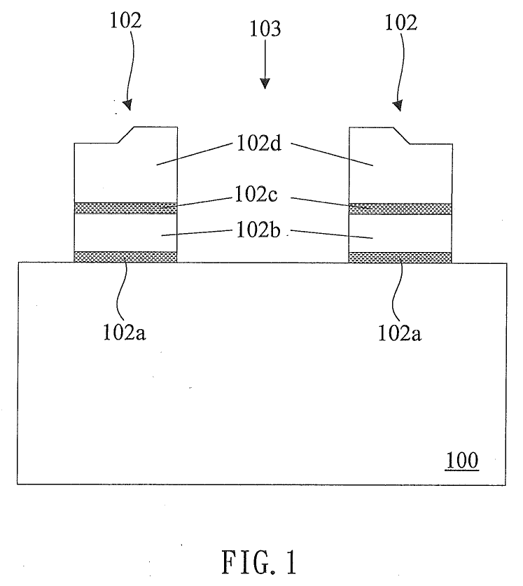

Please refer to FIG. 1, which is a fragmentary sectioned side of view showing some basic parts of the NOR flash memory structure of the present invention. As shown, the NOR flash memory has a semiconductor substrate 100, on which two gate structures 102 are formed. Each of the gate structures 102 includes a tunneling oxide layer 102a, a floating gate 102b, a dielectric layer 102c, and a control gate 102d. A channel 103 is also formed on the semiconductor substrate 100 between the two gate structures 102. The material for the semiconductor substrate 100 can be silicon, silicon-germanium (SiGe), silicon on insulator (SOI), silicon germanium on insulator (SGOI), or germanium on insulator (GOI). In the illustrated embodiments of the present invention, the semiconductor substrate 100 is a silicon substrate.

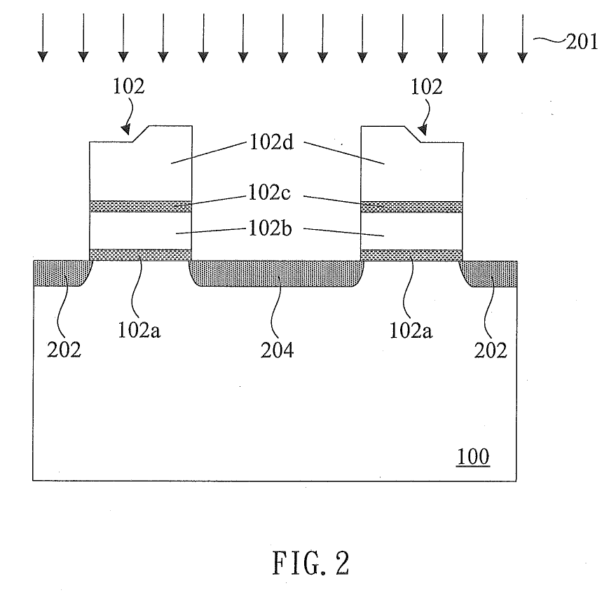

FIG. 2 shows the performing of a lightly-doped ion implantation process 201 on the semiconductor substrate 100. That is, by performing a lightly-doped drain implantation, two lightly-doped source regions 202 and a first drain region 204 are formed on the semiconductor substrate 100 having the two gate structures 102 formed thereon. In the illustrated embodiment of the present invention, the semiconductor substrate 100 is a p-type semiconductor structure, and arsenic (As) ions are used in the lightly-doped ion implantation process 201 at an implant dose of about 1×10¹⁴˜7×10¹⁴ ion/cm² and with an implant energy of about 10˜30 KeV. In the illustrated embodiment of the present invention, the two lightly-doped source regions 202 and the first drain region 204 each are an n-type doped region, and have a junction depth of about 200 Å in the semiconductor substrate 100.

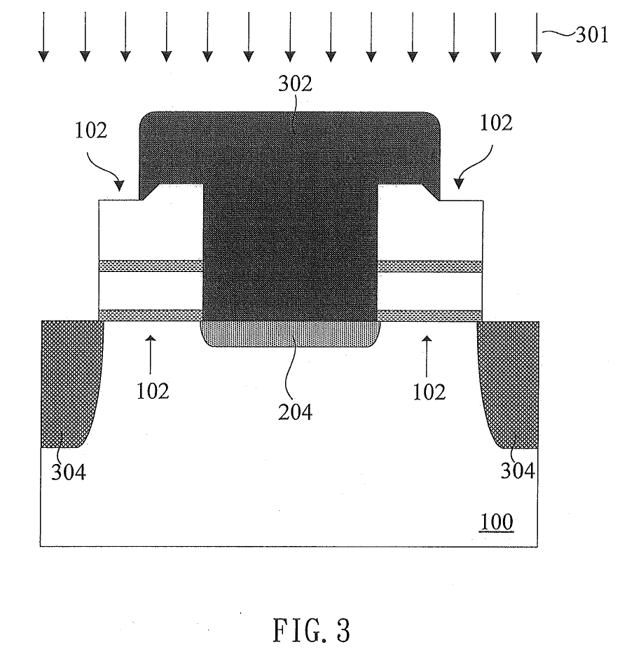

Please refer to FIG. 3 along with FIG. 2. A mask 302 is formed on the semiconductor substrate 100, and the first drain region 204 is covered by the mask 302. Then, a source region ion implantation process 301 is performed to increase the ion implantation depth of the two lightly-doped source regions 202 in the semiconductor substrate 100, so as to form two first source regions 304. The first source regions 304 are not symmetric with respect to the first drain region 204. Similarly, in the p-type semiconductor structure, arsenic (As) ions are used in the source region ion implantation process 301 at an implant dose of about 1×10¹⁴˜7×10¹⁵ ion/cm² and with an implant energy of about 10˜30 KeV. In the illustrated embodiment of the present invention, the first source regions 304 each are an n-type doped source region, and have a junction depth of about 500 to 1500 Å in the semiconductor substrate 100.

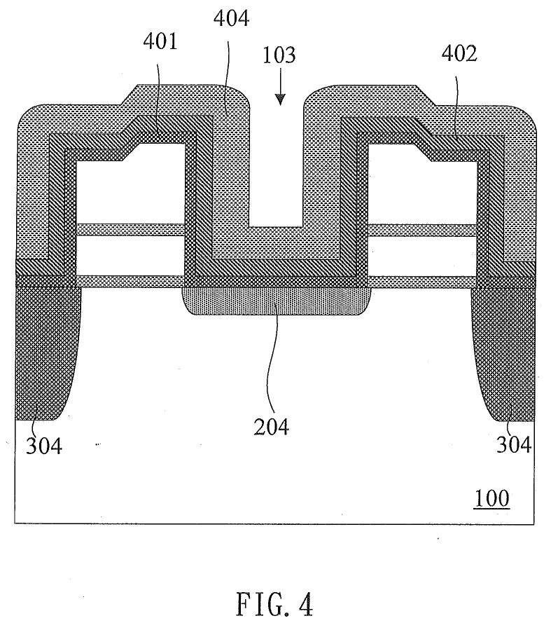

Please refer to FIG. 4. A first oxide wall 401 and a second oxide or nitride layer 402 are formed on the semiconductor substrate 100. And then, a dielectric layer 404 (such like SiOx, SiNx, SiOx/SiNx/SiOx etc.) is deposited through a known deposition technique, such as chemical vapor deposition (CVD) process that uses NH₃ and SiH₄ as the source gases, rapid thermal chemical vapor deposition (RTCVD) process, or atomic layer deposition (ALD) process. The dielectric layer 404 can have a deposition thickness ranged from 200 Å to 1500 Å. In the illustrated embodiment of the present invention, the deposition thickness of the dielectric layer 404 is about 750 Å.

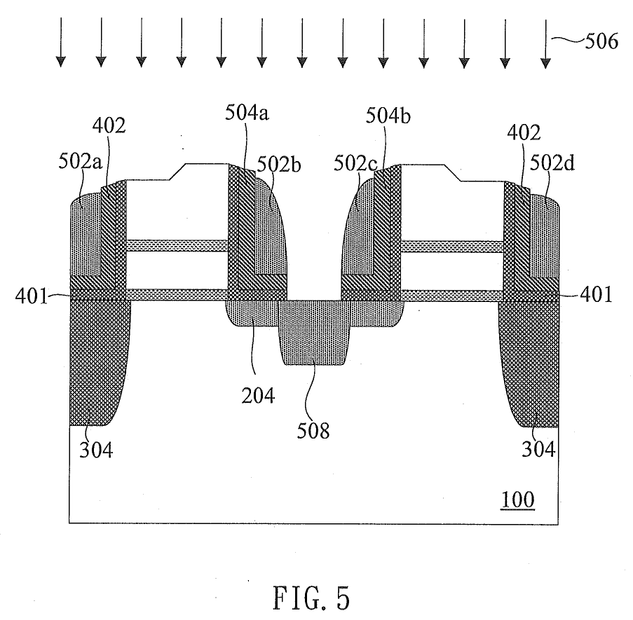

Please refer to FIGS. 4 and 5 at the same time. An etching process, such as dry etching or wet etching, is then performed, so that the dielectric layer 404 is etched to form a plurality of dielectric spacers 502a˜502d. These dielectric spacers 502a˜502d could be L-shaped or fan-shaped. Thereafter, a further etching process is performed, so that the second oxide layer or nitride 402 is etched to form two facing L-shaped or fan-shaped spacer walls 504a, 504b in the channel 103 between the two gate structures 102, and the first oxide wall 401 is also etched. Finally, an HDD ion implantation process 506 is performed to form a highly-doped drain region (HDD) 508 between the two gate structures 102. The HDD region 508 overlaps with the first drain region 204, and has a junction depth in the semiconductor substrate 100 deeper than that of the first drain region 204. In the HDD ion implantation process 506, arsenic (As) ions are used at an implant dose of about 5×10¹⁴˜8×10¹⁵ ion/cm² and with an implant energy of about 20˜55 KeV. And, the junction depth of HDD region 508 in the semiconductor substrate 100 is about 600 Å. The first drain region 204 and the HDD region 508 each have a steep junction profile which is different from a smooth junction profile of the first source regions 304. In the illustrated embodiment, the HDD region 508 is an n-type doped region. Therefore, with the implanted HDD region 508, the memory structure will not be damaged even if the lightly-doped first drain region 204 is punched through due to the relatively shallow junction depth thereof.

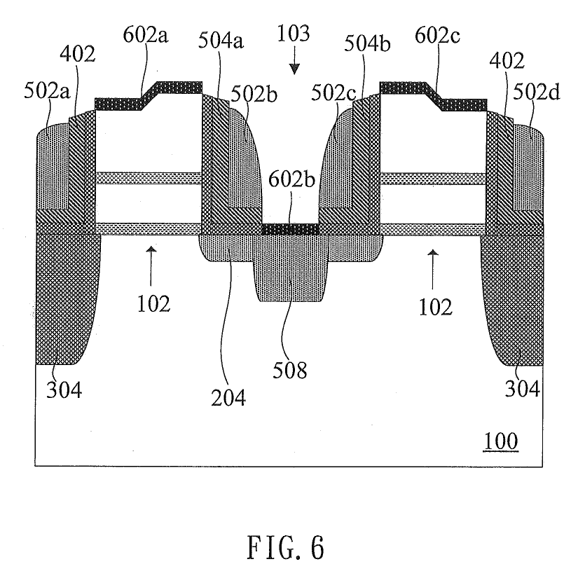

In FIG. 6, a metal silicide layer consisting of cobalt (Co), titanium (Ti), nickel (Ni), or molybdenum (Mo) is formed atop the device obtained in the above step as shown in FIG. 5, and a rapid thermal treatment process is performed, so that three salicide layers 602a, 602b, 602c are separately formed to reduce parasitic resistance and increase device driving force of the flash memory device.

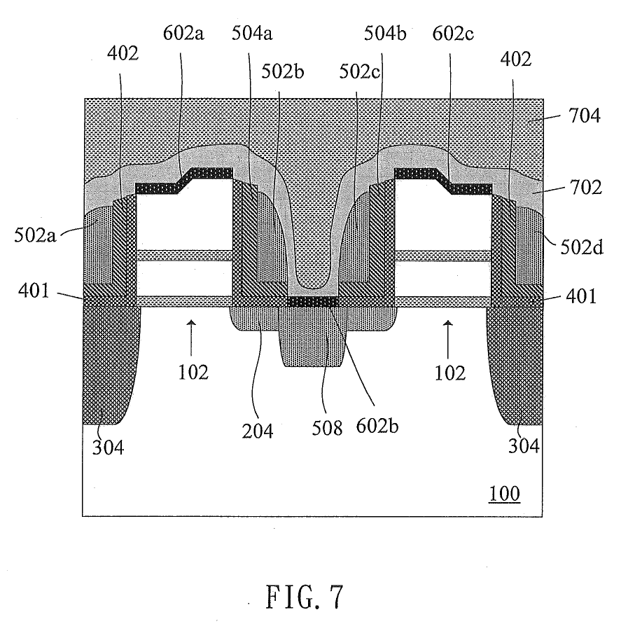

Please refer to FIG. 7. After the above-described steps, a contact etch stop layer (CESL) 702 is deposited on the semiconductor substrate 100. The CESL 702 can be SiN, silicon oxynitride, silicon oxide, etc. In the illustrated embodiment of the present invention, the CESL 702 is SiN. The CESL 702 has a deposition thickness ranged from 100 Å to 1500 Å. Thereafter, an inter-layer dielectric (ILD) layer 704, such as SiO₂, is deposited onto the CESL 702.

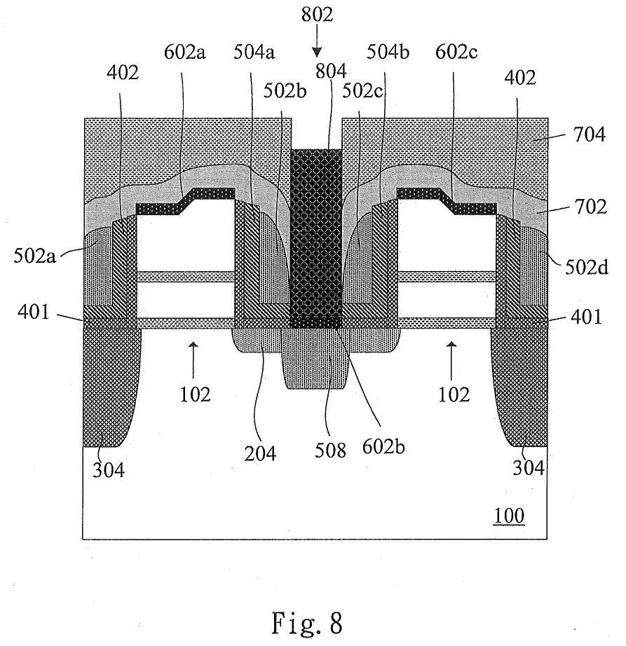

Finally, through a known photoresist and mask process, a contact hole 802 is formed in the channel 103 by anisotropic etching to extend from the inter-layer dielectric 704 to the CESL 702. Then, a barrier plug 804 is deposited in the contact hole 802 to form the NOR flash memory structure with highly-doped drain region according to the present invention, as shown in FIG. 8.

The present invention has been described with a preferred embodiment thereof and it is understood that the illustrated preferred embodiment is used only to describe part of the structure of a memory cell manufactured using the method of the present invention and is not intended to limit the scope of the present invention. It is also understood many changes and modifications in the described embodiment can be carried out without departing from the scope and the spirit of the invention that is intended to be limited only by the appended claims.

What is claimed is:

1. A NOR flash memory structure with highly-doped drain region, comprising:
a semiconductor substrate having two gate structures formed thereon;
a first drain region being a light-doped region and located in the semiconductor substrate between the two gate structures;
two first source regions located in the semiconductor substrate at two outer sides of the two gate structures, and the first source regions each having a junction depth in the semiconductor substrate deeper than that of the first drain region;
a highly-doped drain (HDD) region located in the semiconductor substrate between the two gate structures to overlap with the first drain region, and the HDD region having a junction depth in the semiconductor substrate deeper than that of the first drain region;
two salicide layers separately located atop the two gate structures; and
a barrier plug for isolating the two gate structures from each other.

2. The NOR flash memory structure with highly-doped drain region as claimed in claim 1, wherein the first drain region, the first source regions, and the HDD region each are an n-type doped region.

3. The NOR flash memory structure with highly-doped drain region as claimed in claim 1, further comprising a salicide layer located atop the first drain region.

4. A method of manufacturing NOR flash memory structure with highly-doped drain region, comprising the following steps:
providing a semiconductor substrate;
forming two gate structures on the semiconductor substrate;
performing a lightly-doped ion implantation process, so that a lightly-doped first drain region is formed in the semiconductor substrate between the two gate structures, and two lightly-doped source regions are formed in the semiconductor substrate at two outer sides of the two gate structures; and then further performing a source region ion implantation process, so that two first source regions are formed in the semiconductor substrate at two outer sides of the two gate structures; wherein the first source regions each have a junction depth in the semiconductor substrate deeper than that of the first drain region;
forming two facing spacer walls between the two gate structures, and the two facing spacer walls being located above the first drain region;
performing a highly-doped ion implantation process, so that a highly-doped drain (HDD) region is formed between the two gate structures to overlap with the first drain region; and the HDD region having a junction depth in the semiconductor substrate deeper than that of the first drain region; and
forming a barrier plug between the two gate structures.

5. The method as claimed in claim 4, wherein the step of forming two facing spacer walls between the two gate structures further comprising the following steps:
depositing an dielectric layer on the two facing spacer walls;
etching the dielectric layer until the top surface of the first drain region; and
forming a salicide layer on each of the two gate structures and the first drain region.

6. The method as claimed in claim 4, wherein arsenic ions are used in the lightly-doped ion implantation process at an implant dose of about 1×10¹⁴˜7×10¹⁴ ion/cm² and with an implant energy of about 10˜30 KeV.

7. The method as claimed in claim 4, wherein arsenic ions are used in the source region ion implantation process at an implant dose of about 1×10¹⁴˜7×10¹⁵ ion/cm² and with an implant energy of about 10˜30 KeV.

8. The method as claimed in claim 4, wherein arsenic ions are used in the highly-doped ion implantation process at an implant dose of about 5×10¹⁴˜8×10¹⁵ ion/cm² and with an implant energy of about 20˜55 KeV.
